(19) United States
(12) Patent Application Publication
(10) Pub. No.: US 2020/0036381 A1
(43) Pub. Date: Jan. 30, 2020

(54) CONTROL APPARATUS AND METHOD FOR CONTROLLING OPERATION OF A COMPONENT

(71) Applicant: JAGUAR LAND ROVER LIMITED, COYENTRY, WARWICKSHIRE (GB)

(72) Inventor: ASHUTOSH TOMAR, Warwickshire (GB)

(21) Appl. No.: 16/491,429

(22) PCT Filed: Mar. 1, 2018
(86) PCT No.: PCT/EP2018/055011

§ 371 Date: Sep. 5, 2019

(30) Foreign Application Priority Data
Mar. 6, 2017 (GB) 1703580.9

(51) Int. Cl. H03K 17/96; G06F 3/01; G06F 3/041; G06F 3/044

(52) U.S. Cl. CPC H03K 17/962; H03K 17/964; H03K 17/9645; B60K 37/06; G06F 3/0414; G06F 3/044; H03K 2217/94036; G06F 3/017

(57) ABSTRACT

Embodiments of the present invention provide a control apparatus (400, 500, 600) for controlling operation of a component; a control unit; component; a vehicle and a method for operation of the control apparatus (400, 500, 600). The control apparatus (400, 500, 600) comprises a user-interaction surface visible to a user of the apparatus, a first pressure sensing means (202, 402, 502, 602) horizontally adjacent to a gesture sensing means (204, 404). The first pressure sensing means (202, 402, 502, 602) is adapted to detect a first press input and the gesture sensing means (204, 404) is adapted to detect a gesture input, such that movement of a finger to provide the first press input and the gesture input are combinable to form a single command for controlling operation of the component.

### TECHNICAL FIELD

The present disclosure relates to a control apparatus and method for controlling operation of a component. In particular, but not exclusively, the invention relates to a control apparatus including sensing means for receiving inputs in relation to operation of the apparatus. The control apparatus has particular but not exclusive application in a vehicle. Aspects of the invention relate to a control apparatus for a component, to a component, a vehicle, and to a method.

### BACKGROUND

Modern day motor vehicles have numerous different systems and subsystems which require electronic control units (ECUs), or controllers, to power and control their functionality. Examples of the control units required include those for the various air bags distributed around the vehicle cabin, interior lights, front and rear seats, the entertainment module and/or DVD players, parking aids, various motion and other sensors, the power steering unit, and the terrain and navigation systems, to name but a few. Further electronic control units are also required to control the powertrain and the vehicle engine.

Many of the controllers include user interfaces such as switches and the like. Certain of these interfaces may have stricter requirements in relation to their mode of operation so as to improve user convenience. For example, it may be more important to avoid inadvertent operation of systems and subsystems controlled by certain control apparatus. In this way, the manner in which the user interacts with these controllers must be carefully considered.

It is an object of embodiments of the invention to at least mitigate one or more of the problems of the prior art.

### SUMMARY OF THE INVENTION

Aspects and embodiments of the invention provide a control apparatus for a component, to a component, a vehicle, and to a method as claimed in the appended claims.

According to an aspect of the invention, there is provided a control apparatus for controlling operation of a component, the apparatus comprising a first pressure sensing means adjacent to a gesture sensing means, the first pressure sensing means being adapted to detect a first press input and the gesture sensing means being adapted to detect a gesture input at the control apparatus, such that the first press input and the gesture input combine to form a command for controlling operation of the component.

According to an aspect of the invention, there is provided a control apparatus for controlling operation of a component, the control apparatus comprising a user-interaction surface visible to a user of the apparatus, in use, and a first pressure sensing means adjacent to a gesture sensing means, the first pressure sensing means being adapted to detect a first press input and the gesture sensing means being adapted to detect a gesture input proximal to the control apparatus, wherein the first pressure sensing means and the gesture sensing means are horizontally adjacent beneath the user-interaction surface, such that movement of a finger to provide the first press input and the gesture input are combinable to form a single command for controlling operation of the component.

In this way, operation of the component requires two distinct input operations from the user. This increases the robustness of the mode of operation of the control apparatus and reduces the opportunities for inadvertent operation of the component. As such, the control apparatus provides for improved operation of the component. The distinct operations may be carried out using one hand, which is particularly useful for use in a vehicle.

Advantageously the two distinct operations form part of a single command. By single command it is meant that the finger forms one substantially continuous motion.

A control apparatus as described above wherein the first pressure sensing means comprises a pressure sensor and the gesture sensing means comprises a gesture sensor wherein each sensor has an output for providing an indication of the sensed quantity.

Optionally, the gesture sensing means is adapted to detect the direction of the gesture input. Sensing the direction of the gesture input provides a further factor that may be combined to form the command, thus advantageously increasing the robustness of the mode of operation of the control apparatus.

In an embodiment, the gesture sensing means is adapted to detect a swipe input. A swipe input is a user-friendly and efficient gesture to combine with a press input.

The control apparatus may comprise a processor adapted to receive a signal from the gesture sensing means in dependence on the gesture input and a signal from the first pressure sensing means in dependence on the first press input; and adapted to output the command to the component in dependence on the received signals. The processor may have electrical inputs for receiving the signals from the sensing means. The processor may have an electrical output for communicating a command signal to the component.

Optionally, the processor comprises a timing module adapted to monitor the relative timing of the gesture input and the first press input, and the processor is adapted to output the command if the relative timing is within a certain limit. In this way, the user must make the press input and the gesture input within only a limited delay between them. Advantageously, this contributes to the robustness of the mode of operation, providing further protections against inadvertent operation of the component.

In an embodiment, the first press input has a pressure above a first predetermined threshold.

The control apparatus may be adapted to generate a set of commands in dependence on different inputs received. In this way, different combinations of the inputs via the pressure sensing means and the gesture sensing means may be defined as different commands for the component.

Optionally, the gesture sensing means is adapted to detect a gesture input in contact with the control apparatus. In this way, the user is required to touch the control apparatus to generate the gesture input.

In an embodiment, the gesture sensing means are adapted to detect a gesture input in proximity to the control apparatus. In this way the control apparatus can be optionally configured to cater for an incidence where a user's touch is inadvertently and momentarily not in contact with the gesture sensing means. Additionally, the control apparatus can be configured differently according to the required interactions associated with different situations or usage.

The control apparatus may comprise a second pressure sensing means separated from the first pressure sensing means by the gesture sensing means, wherein the command includes a second press input at the second pressure sensing means. Advantageously, this further increases the robustness of the mode of operation of the control apparatus by providing a third required input to generate a command. Additionally, the option of a third input is useful in allowing a set of commands to be generated by different combinations of user inputs.

Optionally, the second press input has a pressure above a second predetermined threshold In an embodiment, the first threshold input is equal to the second threshold input.

The processor is adapted to receive a signal from the second pressure sensing means in dependence on the second press input; and is adapted to output the command to the component in dependence on the received signals.

Optionally, the timing module of the processor is adapted to monitor the relative timing of the gesture input, the first press input, and the second press input; and the processor is adapted to output the command if the relative timing are within a certain limit.

In an embodiment, the control apparatus may be formed from at least a first sensing layer implementing the first pressure sensing means; a second sensing layer implementing the gesture sensing means; a circuit-carrying layer, and an injection moulded layer. Such a structure has the advantages of being convenient to manufacture and in the final version provides a lightweight yet robust control apparatus that occupies little accommodation space in the component in which it is used.

The control apparatus may be at least partially flexible.

Optionally, the sensing means are implemented using printed electronics.

In an embodiment, the gesture sensing means may comprise a piezoelectric sensing means.

The gesture sensing means may comprise a resistive sensing means. In an embodiment, the resistive sensing means may comprise force sensitive resistive ink.

The capacitive sensing means may comprise a plurality of capacitive sensing elements. In an embodiment the plurality of capacitive sensing elements may be arranged side by side, having increasing distance from the first pressure sensing means. Advantageously, this allows the direction of a gesture traversing the sensing means to be detected my monitoring the change in output of each capacitive sensing element.

In an embodiment the first pressure sensing mean or second pressure sensing means may comprises a piezoelectric sensing means.

Optionally, the first pressure sensing means or second pressure sensing means comprises a resistive sensing means.

The first pressure sensing means or second pressure sensing means may comprise a capacitive sensing means.

The capacitive sensing means may comprise a plurality of portions arranged in relation to one-another. The capacitive sensing means may be shaped as a chevron. Advantageously the chevron shape may improve accurate detection of the gesture.

According to another aspect of the invention, there is provided a component controlled by the control apparatus described previously. In an embodiment, the component may form part of a vehicle. For example, the component may be a sunroof or the like in a vehicle.

According to a further aspect of the invention, there is provided a control unit incorporating the control apparatus.

According to a yet another aspect of the invention, there is provided a vehicle comprising a component controlled by the control apparatus described previously.

According to a further aspect of the invention, there is provided a method of controlling operation of a component comprising receiving a first signal in dependence on a first press input at a first sensing means; receiving a second signal in dependence on a gesture input at a gesture sensing means; and outputting a command for the component if the signals indicate a combination of inputs matching a predefined combination of inputs.

According to a further aspect of the invention, there is provided a method of controlling operation of a component comprising receiving a first signal in dependence on a first press input at a first pressure sensing means arranged beneath a user-interaction surface visible to a user, receiving a second signal in dependence on a gesture input at a gesture sensing means arranged beneath the user-interaction surface horizontally adjacent to the pressure sensing means, and outputting a command for the component if the signals indicate movement of a finger to provide single command comprising a combination of inputs matching a predefined combination of inputs.

Optionally, the method comprises receiving a third signal in dependence on a second press input at a second sensing means.

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

### BRIEF DESCRIPTION OF THE DRAWINGS

FIG. 1 is a schematic diagram of a known vehicle to show the positions of various electronic control units located around the vehicle.

One or more embodiments of the invention will now be described by way of example only, with reference to the accompanying drawings, in which:

FIG. 2 shows a block diagram of an embodiment of the invention;

FIG. 3 shows a block diagram of an alternative embodiment of the invention;

FIG. 4 shows an illustrative representation of a control apparatus according to an embodiment of the invention;

FIG. 5 shows an illustrative representation of a control apparatus according to an embodiment of the invention;

FIG. 6 shows an illustrative representation of a control apparatus according to an embodiment of the invention;

FIG. 7(a) is a flow chart of an embodiment of the invention;

FIG. 7(b) is a flow chart of a further embodiment of the invention;

FIG. 7(c) is a flow chart of a still further embodiment of the invention;

FIG. 8 is an exploded view of a control unit of an embodiment of the invention which may be used in a vehicle of the type shown in FIG. 1 and FIG. 23;

FIG. 9 is a plan view of a printed electronics layer forming part of an example assembly according to the construction shown in FIG. 8;

FIG. 10 is a schematic cross section of the control unit in FIG. 8 formed using a single shot injection moulding process;

FIG. 11 is a schematic cross section of a control unit of a further embodiment, also formed using a single shot injection moulding process;

FIG. 12 is a schematic cross section of a portion of a control apparatus according to an embodiment of the invention;

FIG. 13 is a schematic cross section of a further portion of a control apparatus according to an embodiment of the invention;

FIG. 14(a) is an exploded view of an embodiment of resistive pressure sensing means for use in an embodiment of the invention;

FIG. 14(b) is a perspective view of the assembled resistive pressure sensing means of FIG. 14(a);

FIG. 15 is a cross section view of a piezoelectric pressure sensor suitable for use as pressure sensing means;

FIG. 16 is an exploded view of a cross-section schematic of an embodiment of a control apparatus according to an embodiment of the invention;

FIG. 17 is an exploded view of a cross-section schematic of an embodiment of a control apparatus according an embodiment of the invention;

FIG. 18 is a cross-section schematic of the embodiment of the control apparatus according to the invention shown in FIG. 16;

FIG. 19 is a schematic cross section of a further embodiment of control unit, formed using a twin shot injection moulding process;

FIG. 20 is a schematic cross section of a still further embodiment of a control unit, also formed using a twin shot injection moulding process;

FIG. 21 is a perspective view of another embodiment of control unit with only partial encapsulation of the printed electronics layer;

FIG. 22 is a schematic perspective view of a control unit of a still further embodiment formed by a lamination process;

FIG. 23 is a perspective view of a vehicle according to an embodiment of the invention; and

FIG. 24 is an illustration of simulated electric field around a capacitive sensing element according to an embodiment of the invention.

### DETAILED DESCRIPTION

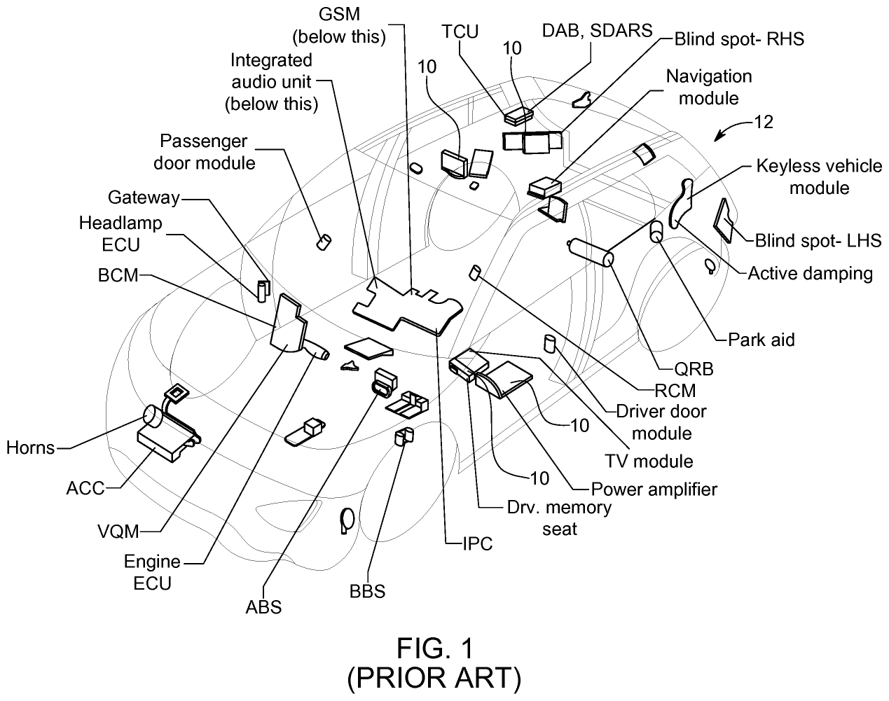

Referring to FIG. 1, in a modern day vehicle the various functions within the vehicle cabin, together with the engine and power train systems, require numerous control units (or controllers) to be situated in already limited accommodation space within the vehicle. FIG. 1 illustrates just some of the possible positions for the control units, some of which are identified with reference numeral 10, which may be distributed throughout the vehicle 12. It is not uncommon, for example, for a vehicle to be provided with in excess of 70 such control units 10, including those for the cabin lighting systems, the air bags, the sunroof, the roof blinds, the windows, the front and rear seats, the parking sensor system, various other sensor systems around the vehicle and the vehicle entertainment system. Many of the control units may comprise one of more control apparatuses to allow the user to interact with the control unit.

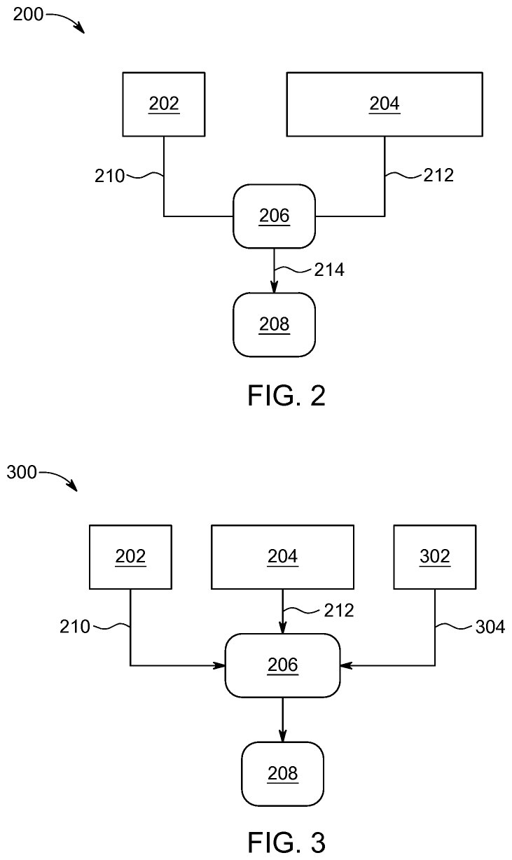

Referring now to FIG. 2, there is shown a block diagram of an embodiment of a component, indicated generally by the reference numeral 200. The component 200 may be a component installed in a vehicle such as that shown in FIG. 1. The component 200 comprises a control apparatus in the form of a first pressure sensing means 202, a gesture sensing means 204 and means to combine their outputs. The component further comprises a processor 206 and an actuator 208. The first pressure sensing means 202 is adapted to receive a first press input from a user. If a press input is received, the first pressure sensing means 202 sends an output signal 210 to the processor 206. The gesture sensing means is adapted to receive a gesture input from a user. If a gesture input is received, the first gesture sensing means 204 sends an output signal 212 to the processor 206. The processor 206 combines the two output signals it has received, analyses the signals and generates a command for the actuator 208, if the signals meet pre-defined requirements.

The first pressure sensing means 202, gesture sensing means 204 and means to combine their output signals, in this case the processor 206 may be considered to form a control apparatus, adapted to generate a control signal for the actuator and so control operation of the component 200.

The first pressure sensing means 202 and gesture sensing means 204 are located horizontally adjacent each other such that a user may move her finger quickly and easily from one to the other. This arrangement allows the user to perform a single movement that engages the two different sensing means so as to complete a single command for controlling operation of the component. The user may be unaware that they have in fact completed two separate movements. In this way, a two-part command that reduces inadvertent activation of the component is provided for without requiring the user to carry out two separate movements.

It will be understood that the term horizontally adjacent is intended to mean that the first pressure sensing means 202 and gesture sensing means 204 are located next to one-another. The first pressure sensing means 202 and gesture sensing means 204 are located proximal to each other in a generally horizontal plane such that movement of the user's finger between the pressure sensing means 202 and gesture sensing means 204 forms the single command In some embodiments, the pressure sensing means 202 and gesture sensing means 204 are contiguous i.e. located immediately adjacent in the horizontal plane. The pressure sensing means 202 and gesture sensing means 204 may horizontally abut one another in some embodiments. The pressure sensing means 202 and gesture sensing means 204 may be arranged so as not to overlap vertically.

The pressure sensing means 202 may comprise a pressure sensor that will react to a press input from a user. The pressure sensing means may comprise a piezoelectric pressure sensor, a resistive pressure sensor, a capacitive pressure sensor, a mechanical pressure sensor or other suitable sensor. Depending on the type of pressure sensor used, the output signal 210 may be analogue value indicative of the pressure applied to the pressure sensor. Alternatively, it may be a simple signal value simply indicating that a pressure above a defined threshold has been applied, for example a signal equivalent to a binary 1. If an analogue signal is received by the processor, the processor may analyse the pressure value to determine if it is above a defined threshold.

The gesture sensing means 204 may comprise a sensor that will react to a gesture input from a user. The gesture sensing means may comprise a piezoelectric sensor, a resistive sensor, a capacitive pressure sensor, or other suitable sensor. Typically, the output of the gesture sensing means 204 is processed by the processor 206 to determine characteristics of the gesture input. Such characteristics may include the direction of the gesture, the length of the gesture, the duration of time that the user's finger was in contact with or in proximity to the gestures sensing means, and the like. The gesture input is detected by the gesture sensing means 204 when proximal to the gesture sensing means 204 i.e. within a detection range of the gesture sensing means 204.

The processor 206 may have timing means (not shown) to monitor and analyse the respective timings of inputs from the sensor means. The timing means may analyse the time between the first press input and the gesture input, and if the time between the inputs is too long, the processor 206 will not generate the command to the actuator 208.

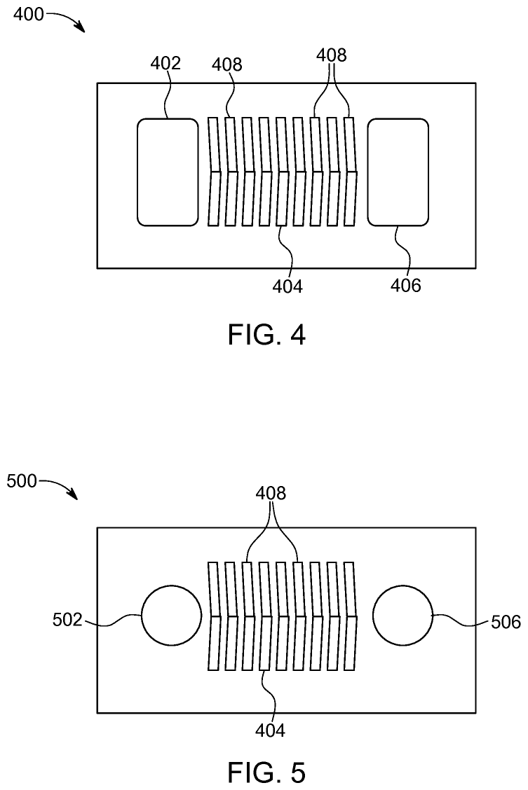

Referring now to FIG. 3, there is shown a block diagram of an alternative embodiment of component, indicated generally by the reference numeral 300. The component 300 includes all of the components, structure and features of the component 200 and therefore to avoid repetition only the additional components, structure and features are described. In this embodiment, the component 300 includes a second pressure sensing means 302. The second pressure sensing means 302 sends a signal 304 to the processor. The second pressure sensing means 302 may be implemented in the same as the first pressure sensing means 202 or may be implemented in a different manner. For example, it may be convenient to have one capacitive sensor and one resistive sensor, so as to allow different pressure ranges can be detected. In this embodiment, the control apparatus is formed by the first pressure sensing means, the second pressure sensing means, the gestures sensing means and means to combine their respective output signals.

Referring now to FIG. 4, there is shown an illustrative top view of an embodiment of a control apparatus, indicated generally by the reference numeral 400. The control apparatus 400 comprises a first pressure sensing means 402, a gesture sensing means 404 and a second pressure sensing means 406. The first pressure sensing means 402 and second pressure sensing means 406 comprise piezoelectric force sensors for detecting press inputs from the user. The gesture sensing means 404 comprise a plurality of capacitive sensing elements 408 for detecting a gesture. Each capacitive sensing element 408 can detect a user's touch or proximity of a user's finger thereto. If a user's finger is swiped along the set of capacitive sensing elements, each subsequent element will detect the finger as it moves over the gesture sensing means 404. In this way, the plurality of capacitive elements can detect a gesture along the length of the set of elements, in particular a swipe between the two pressure sensing means. They can also detect the direction of the gesture and the length thereof.

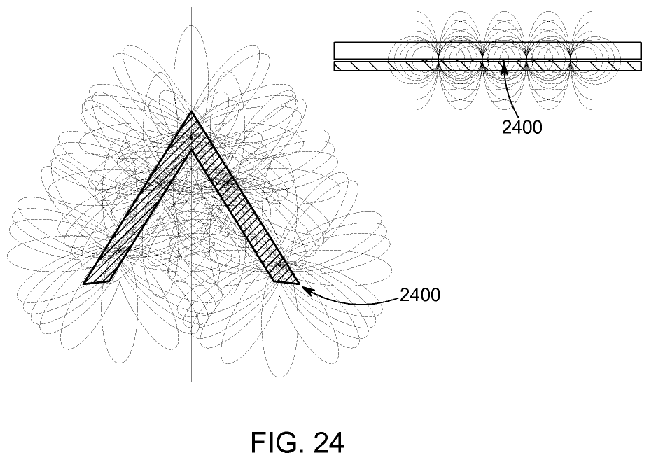

FIG. 24 illustrates a capacitive sensing element 2400 according to an embodiment of the invention. It can be appreciated from FIGS. 4 and 24 that each of the plurality of capacitive sensing elements 408, 2400 are shaped in the form of a chevron or arrow. It will be understood that chevron is understood to mean a V-shaped element. That is, in some embodiments each of the plurality of capacitive sensing elements 408, 2400 comprise first and second arms arranged to intersect at a predetermined angle to one another. The predetermined angle may be less than 180° and more than 90° in some embodiments. Thus, the gesture sensing means 404 in some embodiments comprises a chevron pattern formed by the plurality of capacitive sensing elements 408, 2400. The chevron or V-shape of each of the plurality of capacitive sensing elements 408, 2400 advantageously provides improved debouncing capability of the gesture sensing means 404. Said improved debouncing capability provides improved discrimination between a capacitance value C₁ immediately prior to detecting the user's touch or sensing the proximity of the user's finger thereto and a capacitance value C₂ upon sensing the touch or proximity of the user's finger. In some embodiments, an area A of each capacitive sensing element may be between 10 and 20 mm² or around 15 mm². Such dimensions are approximately equal to an area of a user's fingertip expected to be brought proximal to the capacitive sensing element 2400 thereby improving a capacitive coupling between the fingertip and the capacitive sensing element 2400.

FIG. 24 additionally shows an illustration of electrostatic field lines in a vicinity of the capacitive sensing element 2400 which is shown in both plan and side view in FIG. 24. It has been appreciated by the present inventors that a shape of the capacitive sensing element 2400 influences debouncing i.e. preventing noise being interpreted as an input received at the capacitive sensing element 2400. Particularly if the user and the capacitive sensing element 2400 have different ground voltage references, then the capacitance of the user's fingertip in proximity to the capacitive sensing element 2400 may be wrongly interpreted as noise. As can be appreciated, a total capacitance of the capacitive sensing element 2400 (C_{TOT}) is due to parasitic capacitance (C_{P}) and a capacitance of the user's fingertip (C_{F}) i.e. C_{TOT}=C_{P}+C_{F}.

It has been observed that the shape of the capacitive sensing element 2400 influences the parasitic capacitance C_{P} of the capacitive sensing element 2400. Square and circular shapes of capacitive sensing element were observed to have good sensitivity to the presence of the user's fingertip, but increased a bouncing effect due to electric field being generated by a point source. However, the chevron shape of the capacitive sensing element 2400 creates a planar or more distributed source of electric field, as illustrated in FIG. 24, rather than the point source, which improves a resistance to bouncing i.e. improves debouncing. Furthermore, conducted and radiated noise may have less of an effect on the chevron-shaped capacitive sensing element 2400. Additionally, the chevron-shaped capacitive sensing element 2400 may offer increased design freedom when being utilised to form an array of capacitive sensing elements and may also use less material, such as ink, to form the capacitive sensing element 2400.

It will be apparent to a person skilled in the art that a gesture sensing means 404 of this type can be arranged to generate command signals in response to pressure patterns applied as stokes or taps by a finger or stylus. It will be further apparent to the person skilled in the art that the gesture sensing means 404 may also be implemented using a resistive pressure sensor, a piezoelectric pressure sensor or other suitable sensor. The gesture sensing means may be provided in a groove, sized to fit a finger, such that the user is encouraged to swipe their finger along the groove.

Referring now to FIG. 5, there is shown an illustrative top view of an alternative embodiment of a control apparatus, indicated generally by the reference numeral 500. The control apparatus 500 includes all of the components, structure and features of the control apparatus 400 and therefore to avoid repetition only the additional components, structure and features are described. In this embodiment, the first pressure sensing means 502 and second pressure sensing means 506 of the control apparatus 500 are implemented using mechanical switches, for example dome switches. Users often appreciate the familiar haptic feedback provided by a mechanical switch.

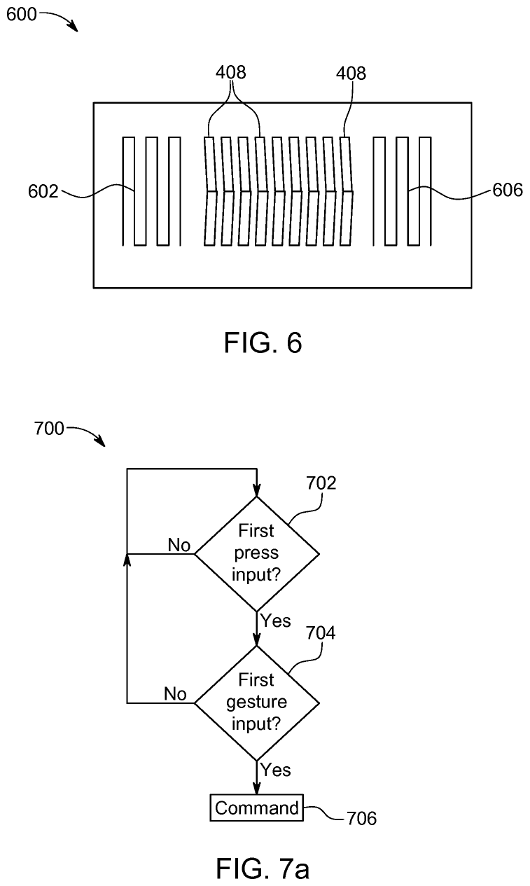

Referring now to FIG. 6, there is shown an illustrative top view of a further embodiment of a control apparatus, indicated generally by the reference numeral 600. The control apparatus 600 includes all of the components, structure and features of the control apparatus 400 and therefore to avoid repetition only the additional components, structure and features are described. In this embodiment, the first pressure sensing means 602 and second pressure sensing means 606 of the control apparatus 600 are implemented using capacitive pressure sensors.

In use, a user will use the control apparatus 400, 500, 600 to generate command for a component. Typically, the component is within a vehicle. In order for the command to be generated, the user will press a finger to the first pressure sensing means then move her finger along the gesture sensing means and finish by pressing on the second pressure sensing means. Each press generates an input signal. The gesture sensing means may generate an input from the presence (in contact or in proximity) of a finger, and may also generate an input relating to the movement of that finger, and finally may generate an input from the detected direction of the movement. The processor may be programmed to react to various combinations of these inputs. One command is defined by a press on the first pressing sensing mean immediately followed by movement on the gesture sensing means, the movement being away from the first sensing means. A further command may be defined as including the same actions as the original command and further including a terminating press input on the second pressure sensing means. Further commands may include the reverse of the commands previously discussed here. For example, if these commands are used for the operation of a vehicle sunroof, then press1-swipe could be defined as the instruction to open the sunroof half way; press1-swipe-press2 could be defined as the instruction to open the sunroof fully; press2-swipe could be defined as the instruction to close the sunroof halfway; and press2-swipe-press1 be defined as the instruction to close the sunroof fully.

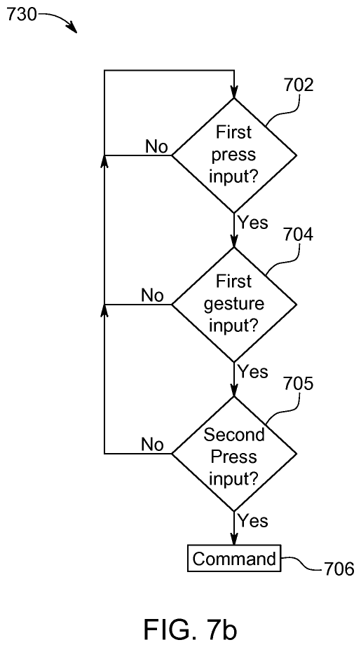

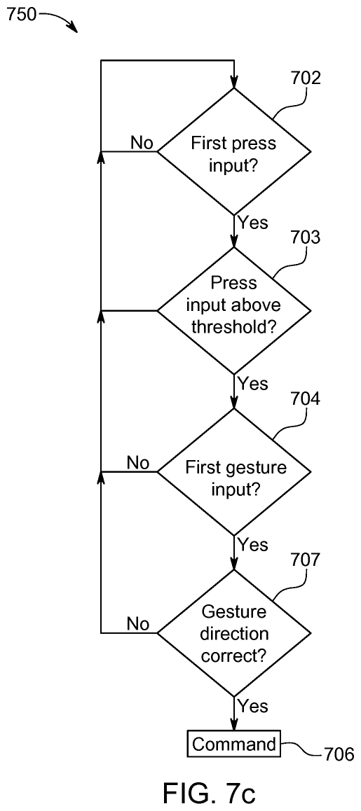

Referring now to FIG. 7(a), there is shown a flowchart for a method, indicated generally by the reference numeral 700, according to an embodiment of the invention. The method 700 comprises a first step 702 wherein the first pressure sensing means are monitored for a first press input from a user. If a first press input is received, the gesture sensing means are examined at step 704 for a gesture input. If the gesture input is received, the command is generated in step 706.

Referring now to FIG. 7(b), there is shown a flowchart for a method, indicated generally by the reference numeral 730, according to a further embodiment of the invention. The method 730 comprises the same initial steps of monitoring the first pressure sensing means 702 for a press input 702 and monitoring the gesture sensing means 704 for a gesture input as the method 700 of the embodiment of FIG. 7(a). However, the method 730 of the embodiment of FIG. 7(b) further comprises the additional 705 of monitoring a second pressure sensor means for a second press input from a user. If the second press input, the command is generated in step 706.

Referring now to FIG. 7(c), there is shown a flowchart for a method, indicated generally by the reference numeral 750, according to a further embodiment of the invention. The method 750 comprises the same initial step of monitoring the first pressure sensing means 702 for a press input 702. The first press input is then checked in step 703 if the pressure of the press input is above a predefined threshold. Step 704 again comprises monitoring the gesture sensing means 704 for a gesture input. In step 707, the detected gesture input is analysed to detect its direction. In step 706, if all of the required inputs have been detected, the command is generated. It will be apparent to the person skilled in the art that the methods of FIG. 7(b) and FIG. 7(c) may be combined such that the second pressure sensing means are analysed to detect if the press input is above a pressure threshold. It will also be understood that the step of detecting the gesture input may simultaneously provide information on the direction of the gesture input. The length of the gesture input may also be detected by the gesture sensing means and considered in relation to the command output.

Referring again to FIG. 1, it can be seen that using so many control units poses a challenge for vehicle manufacturers in finding accommodation space within the vehicle to house the units. In some current vehicles there can be as many as 80 different control units distributed throughout the vehicle. In addition to the problem of space for housing the control units, the wiring for the units and the weight that the units contribute to the vehicle is also a disadvantage.

A particular challenge with known control units is the limitation of their shape and size which restricts where the units can be housed. Traditionally control units are formed of a printed circuit board containing various electronic components and wiring which are housed within a rigid casing. The units need to be hidden within the vehicle, for aesthetic and operational reasons, and are often located behind the trim panels in the cabin. However space is limited in these regions and the inflexible design of the packaging for the control units means they cannot readily be accommodated in restricted spaces. Where a control unit comprise a control apparatus according to an embodiment of the invention, the location of the control unit in question may be even more limited. For example, the control apparatus for a sunroof or electric window may be located near the sunroof or window.

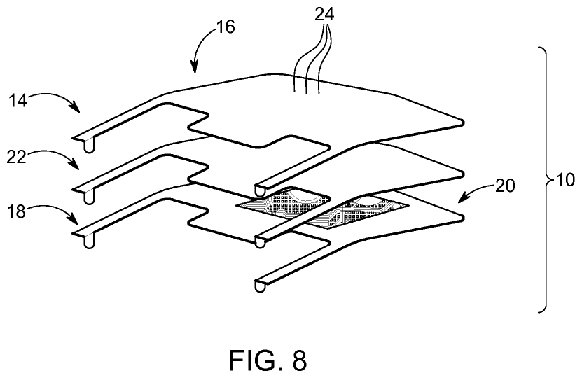

FIG. 8 is an exploded view of the control unit 10, which by contrast with existing control units provides a compact and relatively light weight structure that can be housed more readily within the confines of the vehicle cabin. The control unit comprises three elements or members; a first member 14 which defines a presentation surface 16 to the user which is visible to the user when the control unit is installed in its operating location. The presentation surface may be referred to as the A-surface 16 of the control unit. The presentation surface 16 defines a user-interaction surface 16 for receiving a user command. The user-interaction surface 16 is thus visible in use to a user of the control unit 10. The first pressure sensing 202 means and the gesture sensing means 204 are horizontally adjacent beneath the user-interaction surface 16. The user command may be provided by movement of the user's finger along, or proximal to, the user-interaction surface.

The control unit 10 further comprises a second member 18 which defines a B-surface 20 of the unit, and an intermediate member in the form of an injection moulded layer 22 interposed between the first and second members 14, 18. Typically in a vehicle, reference to an “A-surface” is a surface which is presented to a user of the vehicle and/or with which a vehicle user interacts, for example for the purpose of initiating control of a function within the vehicle, whereas a “B-surface” is a non-interacting surface that is usually hidden from the view of the user. The A- and B-surfaces may be defined by opposed surfaces of the same member, or as is shown in FIG. 8 may be defined by separate members 14, 18 which are separate from one another.

It will be appreciated from the following description that either the first or the second member may form the circuit-carrying member of the control unit 10 (i.e. that component upon which the electronic circuit is printed). The phrase ‘member’ may be taken to mean any part, element, layer or other component of the control unit.

The first and second members 14, 18 are generally plate-like members, but in other configurations may take the form of thinner members, and even flexible layers, as discussed in further detail below. The first and second members 14, 18 are pre-formed members. The pre-formed first and second members 14, 18 are placed in the injection mould prior to the injection moulding process which produces the control unit 10 by forming layer 22.

Referring to FIG. 8, the A-surface is defined by a first thermoformed member 14 which is pre-formed by first heating a plastic sheet to a pliable temperature, and then laying the sheet in a mould so that the plastic material adopts the shape of the mould before it is then cooled. Graphical features 24 (only a few of which are labelled) are applied to the A-surface 16 to provide features, such as icons or symbols, which provide an indication to the vehicle user about how to control various functions provided by the finished control unit. Typically the graphical features are applied by laying a printed layer into the mould to define the required graphical icons and symbols. A three-dimensional finger track or groove (not visible in FIG. 8) is provided on the A-surface into which a user can place their finger to run their finger along the track, optionally applying pressure to the surface or through capacitive touch to initiate a control of a vehicle function as described in further detail below. The A-surface 16 typically defines a visible surface in the vehicle cabin with which the user interacts. For example, the A-surface may provide a surface of an arm rest, an overhead control panel, a tray table, a seat control switch pack, a glove box lid, or a part of the vehicle dashboard.

The B-surface 20 is defined by a second thermoformed member 18, formed in the same way as described previously for the first member, to which a plurality of active and passive electronic components and printed tracks or wires are applied using known techniques. Typical passive components take the form of resistors, capacitors, inductors and transformers and diodes, whereas typical active components are those which act upon a source of current, such as amplifiers, switches, light emitting diodes (LEDs), integrated circuits, memories and microcontrollers. Typically, the B-surface 20 may be provided with one or more of the following features; an integrated circuit, a microprocessor, light emitting diodes (LEDs), user-interactive components such as pressure sensitive track, grid sensors, resistors, antennae, capacitors, sensors, quartz clocks, inductors, and conductive prints or tracks for carrying current. Known techniques for printing of the wires and tracks onto the B-surface 20 include screen printing, flexo printing, gravure, offset lithography, inkjet, aerosol deposition or laser printing.

Being pre-formed, thermoformed parts, the first and second members 14, 18 are lightweight and robust in nature, and can be formed with an aesthetically pleasing shape, contour and/or finish. This is particularly relevant for the A-surface 16 which provides the interaction surface for the user and is visible to the user within the vehicle cabin. The thermoforming process also enables a whole host of different shapes to be achieved for the members 14, 18. In the present embodiment the first and second members 14, 18 are generally planar with a slight curvature on their upper surfaces. In other embodiments, for example, the members may be more fully curved or rounded, at least in part, as determined by the shape of the available accommodation space which they are intended to occupy within the vehicle. Typical materials from which the first and second members 14, 18 are formed include polycarbonate materials or thermoplastic polymer resins such as polyethylene terephthalate (PET). Other examples of injection moulding engineered thermoplastic materials include polyphenylene sulfide (PPS), polyether sulfone, acetals, polypropylenes, polyether imide (PEI), polyethylenes, polyphenylene oxide (PPO), acrylonitrile butadiene styrene, polyurethanes (PUR), thermoplastic elastomers, polyphthalamide (PPA), polyethylene naphthalate (PEN), polyimide (PI), including plexiglass.

In other embodiments of the invention the first and second members 14, 18 may take the form of vacuum formed elements or members, as opposed to thermoformed elements or members. Other pre-forming methods may also be used to produce the ‘pre-formed’ members 14, 18, prior to performing the injection moulding process.

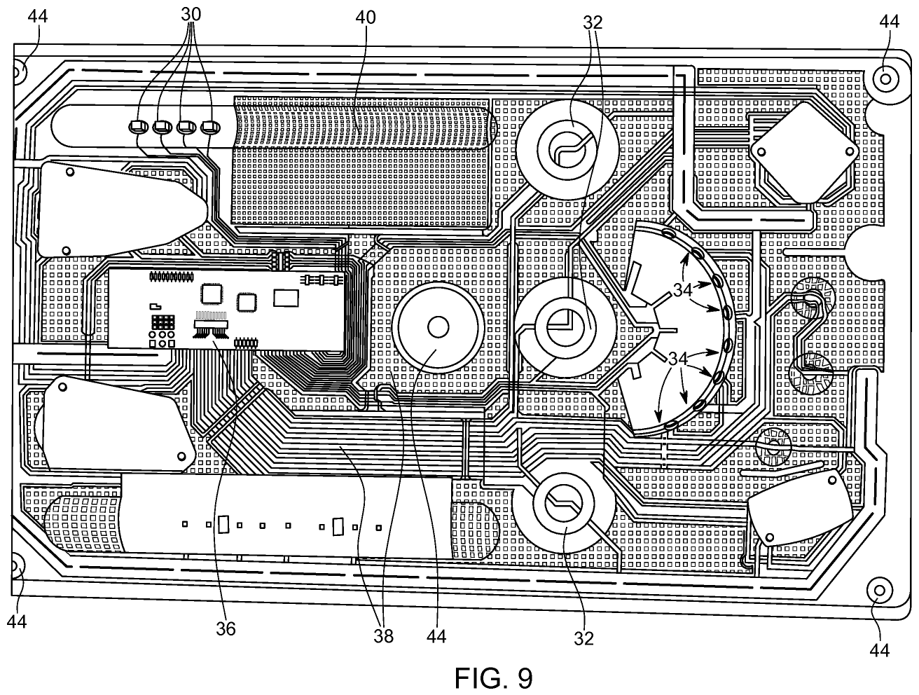

FIG. 9 shows an example of a B-surface 20 which may form a part of the second member 18 of the control unit 10 in FIG. 8. When in situ within the vehicle the B-surface 20 may define at least a part of an overhead control panel for controlling various lighting functions in the ceiling of the cabin and operation of a vehicle sunroof and/or roof blinds.

The B-surface 20 is provided with a printed electronics layer including a first set 30 of four LEDs provided in a horizontal arrangement in a first zone (top left) of the surface, a second set 32 of three LEDs provided in a vertical arrangement in a second zone just to the right of the vertical centreline of the surface and a third set 34 of LEDs provided in an arc arrangement located adjacent to the second zone. It will be appreciated that the use of the terms horizontal and vertical in this description is made with reference to the orientation in the figures, but is not intended to be limiting.

The positions of the first, second and third zones on the B-surface 20 correspond to associated regions on the A-surface 16 which are provided with graphical features to identify the positions of the zones underneath when the members 14, 18 are assembled in a ‘stack’, as indicated in FIG. 8. The four LEDs 30 in the first zone may typically take the form of low level illumination LEDs to provide mood lighting on the ceiling of the vehicle, or to illuminate other features of the control unit. The three LEDs 32 in the second zone may typically take the form of higher power LEDs providing task lights for the vehicle. Various other light sources may be incorporated on the control panel including LEDs for providing ambient lighting effects, LEDs for illuminating hidden-until-lit features, Emergency-call features (E-call features) or Breakdown-call features (B-call features), and LEDs for illuminating icons or graphical features which provide indicators to the user about various functions of the control unit

The B-surface 20 is further provided with a hybrid integrated circuit 36 for controlling and powering the various electronic components 30, 32, 34. Conductive prints or conductive tracks (two of which are identified by 38) are printed on various regions of the B-surface to provide current to the various components 30, 32, 34. In practice a greater number of tracks may be provided than is necessary for each component 30, 32, 34, for reasons which shall be explained later. The conductive tracks 38 include copper tracks (e.g. forming part of the hybrid integrated circuit 36) which provide fast connections to the microcontrollers and microprocessors of the hybrid integrated circuit 36, and silver tracks which carry current from the hybrid integrated circuit 36 to the other components (e.g. components 30, 32, 34) of the printed electronics layer. The substrate for the printed electronics layer may take the form of a polyester (PET), polyethylene naphthalate, polyimide, or plexiglass.

A grid sensing region 40 is provided in a three-dimensional groove formed along the upper edge of the B-surface 20 which corresponds to the position of the aforementioned three-dimensional groove provided in the A-surface. The groove 40 is shaped to receive the groove formation 26 of the A-surface when the members 14, 18 are assembled together. In use, sliding movement of the user's finger along the groove 26 provides a variable control function, or ‘slider’ function (for example using a piezoelectric or capacitive touch function) which may be used in particular to control the opening of a vehicle sunroof, as described in further detail below. The groove and its associated sensing means may be considered as gesture sensing means.

In the centre of the B-surface 20, and in each of the four outermost corners, openings are provided, also referred to as ‘gates’ 44, into which a moulding material is injected in order to form the third member 22 between the first and second members 14, 18. The first and second members 14, 18 are first placed into respective injection moulds with their various features in place, as described previously, and then the material for the intermediate member 22 is injected through the gates 44 into the cavity between the outer members 14, 18. Typically the material that is injected between the first and second members 14, 18 is a polycarbonate material, or other material suitable for injection moulding. Such polycarbonate materials are highly robust and may be transparent. The material is injected into the cavity at high temperature and pressure, and is then cooled so that the material adopts the shape of the cavity between the first and second members 14, 18, to complete the three-layer structure of the control unit shown clearly in FIG. 8. Other suitable materials for the moulded layer include most polymers (resins), including thermoplastics, thermosets, and elastomers. The materials selected for the first and second pre-formed members 14, 18 may be materials which are bendable or foldable in their final state, or may provide a more rigid structure, depending on the application.

The position of the gates 44 is an important feature of the assembly in that the gates need to be positioned in areas where the high pressures and temperatures associated with the injection moulding process do not cause damage to any of the more sensitive and fragile electronic components on the B-surface 20. By way of example with reference to FIG. 8, based on manufacturing process considerations the central gate position is advantageous as it allows a uniform distribution of the injection moulding material between the first and second members 14, 18, to define an intermediate layer 22 of substantially uniform thickness. The gates are positioned so as to disperse the pressure of flow evenly between the surfaces of the members 14, 18. However, it does place the injection point of the central gate in quite close proximity to some of the components on the B-surface 20 (e.g. the LEDs and the integrated circuit). In other embodiments it may be possible to remove the central gate 44 altogether, and to rely only on the corner gates to introduce the injection moulding material between the members 14, 18. However, a balance is needed between the higher pressures required to inject the material into the central region between the members, in order to achieve a uniform layer across the entire surface, and the need to protect sensitive electronic components on the B-surface from such higher pressures. It is most advantageous to locate the more sensitive active components, such as clocks, sensors, antennae and capacitors, in positions on the surface 20 that are remote from or spaced well away from the gates.

Once the moulded layer 22 is formed between the two members 14, 18 the control unit takes its final form, comprising the first member 14 defining the A-surface 16 with graphical features with which the user can interact, the second member 18 defining the B-surface 20 which carries the various electronic components controlled by the user interactions with the A-surface 16, and the moulded layer 22 between the first and second members to provide rigidity and structure to the unit.

Control units having a construction as described in relation to FIG. 8 provide the advantage that it is convenient to manufacture, and in the final version provides a lightweight yet robust control unit that occupies little accommodation space in the apparatus in which it is used.

FIG. 9 shows one example of a B-surface 20 which may form a part of the second member 18 in the control unit 10 in FIG. 8. When in situ within the vehicle the B-surface 20 may define at least a part of an overhead control panel for controlling various lighting functions in the ceiling of the cabin and operation of a vehicle sunroof and/or roof blinds.

The B-surface 20 is provided with a printed electronics layer including a first set 30 of four LEDs provided in a horizontal arrangement in a first zone (top left) of the surface, a second set 32 of three LEDs provided in a vertical arrangement in a second zone just to the right of the vertical centreline of the surface and a third set 34 of LEDs provided in an arc arrangement located adjacent to the second zone. It will be appreciated that the use of the terms horizontal and vertical in this description is made with reference to the orientation in the figures, but is not intended to be limiting.

The positions of the first, second and third zones on the B-surface 20 correspond to associated regions on the A-surface 16 which are provided with graphical features to identify the positions of the zones underneath when the members 14, 18 are assembled in a ‘stack’, as indicated in FIG. 8. The four LEDs 30 in the first zone may typically take the form of low level illumination LEDs to provide mood lighting on the ceiling of the vehicle, or to illuminate other features of the control unit. The three LEDs 32 in the second zone may typically take the form of higher power LEDs providing task lights for the vehicle. Various other light sources may be incorporated on the control panel including LEDs for providing ambient lighting effects, LEDs for illuminating hidden-until-lit features, Emergency-call features (E-call features) or Breakdown-call features (B-call features), and LEDs for illuminating icons or graphical features which provide indicators to the user about various functions of the control unit 10.

The B-surface 20 is further provided with a hybrid integrated circuit 36 for controlling and powering the various electronic components 30, 32, 34. Conductive prints or conductive tracks (two of which are identified by 38) are printed on various regions of the B-surface to provide current to the various components 30, 32, 34. In practice a greater number of tracks may be provided than is necessary for each component 30, 32, 34, for reasons which shall be explained later. The conductive tracks 38 include copper tracks (e.g. forming part of the hybrid integrated circuit 36) which provide fast connections to the microcontrollers and microprocessors of the hybrid integrated circuit 36, and silver tracks which carry current from the hybrid integrated circuit 36 to the other components (e.g. components 30, 32, 34) of the printed electronics layer. The substrate for the printed electronics layer may take the form of a polyester (PET), polyethylene naphthalate, polyimide, or plexiglass.

A grid sensing region 40, adapted to operate as a gesture sensing means, is provided in a three-dimensional groove formed along the upper edge of the B-surface 20 which corresponds to the position of the aforementioned three-dimensional groove provided in the A-surface. The groove 40 is shaped to receive the groove formation 26 of the A-surface when the members 14, 18 are assembled together. In use, sliding movement of the user's finger along the groove 26 provides a variable control function, or ‘slider’ function (for example using a piezoelectric or capacitive touch function) which may be used in particular to control the opening of a vehicle sunroof, as described in further detail below.

In the centre of the B-surface 20, and in each of the four outermost corners, openings are provided, also referred to as ‘gates’ 44, into which a moulding material is injected in order to form the third member 22 between the first and second members 14, 18. The first and second members 14, 18 are first placed into respective injection moulds with their various features in place, as described previously, and then the material for the intermediate member 22 is injected through the gates 44 into the cavity between the outer members 14, 18. Typically the material that is injected between the first and second members 14, 18 is a polycarbonate material, or other material suitable for injection moulding. Such polycarbonate materials are highly robust and may be transparent. The material is injected into the cavity at high temperature and pressure, and is then cooled so that the material adopts the shape of the cavity between the first and second members 14, 18, to complete the three-layer structure of the control unit 10 shown clearly in FIG. 8. Other suitable materials for the moulded layer include most polymers (resins), including thermoplastics, thermosets, and elastomers. The materials selected for the first and second pre-formed members 14, 18 may be materials which are bendable or foldable in their final state, or may provide a more rigid structure, depending on the application.

The position of the gates 44 is an important feature of the assembly in that the gates need to be positioned in areas where the high pressures and temperatures associated with the injection moulding process do not cause damage to any of the more sensitive and fragile electronic components on the B-surface 20. By way of example with reference to FIG. 8, based on manufacturing process considerations the central gate position is advantageous as it allows a uniform distribution of the injection moulding material between the first and second members 14, 18, to define an intermediate layer 22 of substantially uniform thickness. The gates are positioned so as to disperse the pressure of flow evenly between the surfaces of the members 14, 18. However, it does place the injection point of the central gate in quite close proximity to some of the components on the B-surface 20 (e.g. the LEDs and the integrated circuit). In other embodiments it may be possible to remove the central gate 44 altogether, and to rely only on the corner gates to introduce the injection moulding material between the members 14, 18. However, a balance is needed between the higher pressures required to inject the material into the central region between the members, in order to achieve a uniform layer across the entire surface, and the need to protect sensitive electronic components on the B-surface from such higher pressures. It is most advantageous to locate the more sensitive active components, such as clocks, sensors, antennae and capacitors, in positions on the surface 20 that are remote from or spaced well away from the gates.

Once the moulded layer 22 is formed between the two members 14, 18 the control unit 10 takes its final form, comprising the first member 14 defining the A-surface 16 with graphical features with which the user can interact, the second member 18 defining the B-surface 20 which carries the various electronic components controlled by the user interactions with the A-surface 16, and the moulded layer 22 between the first and second members to provide rigidity and structure to the unit.

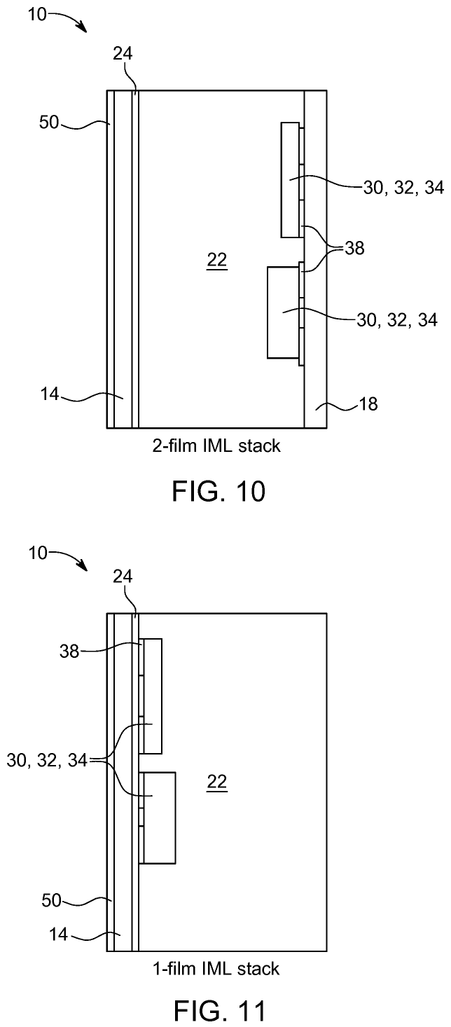

FIGS. 10 and 11 are schematic views of two possible configurations suitable for implementing the control unit 10. The configurations of FIGS. 10 and 11 may be formed using a single shot injection moulding process in which the injection moulding material is introduced into the mould to form the intermediate layer 22 of the control unit 10, as described previously.

In FIG. 10 the graphics layer is laid on the reverse side of the A-surface (which would be transparent to allow visibility of the graphics layer). On top of the A-surface 16, an additional hard coat 50 is applied as a protective surface as this is the surface that is exposed in the vehicle cabin and may be subject to scratches and knocks, in use. In this example the moulded layer 22 is approximately 2-3 mm in thickness, so that the overall structure is relatively thin and lightweight in comparison with known electronic control units. The active electronic components 30, 32, 34 and conductive prints or tracks 38 are applied to the B-surface 20 at the rear of the structure, as described previously. The configuration shown in FIG. 10 can be formed using a single-shot injection moulding process to form the intermediate layer 22.

In addition, a piezoelectric layer (not shown) may be laid immediately beneath the first member 14 (i.e. in intimate contact with or in very close proximity to the first member 14). The piezoelectric layer is a pressure-sensitive layer via which the underlying electronic components 30, 32, 34 are controlled by the user applying a pressure to the surface of the first member 14 to provide a piezoelectric control function for the underlying electronic components 30, 32, 34.

In other embodiments (not shown), electrode and dielectric layers may be provided in the layer-structure of the control unit 10 to provide a capacitive touch functionality for the unit. The electrode layer and dielectric layers may be provided by the conductive tracks (such as 38). In this configuration a small voltage is applied to conductive tracks on the second member 18, resulting in a uniform electrostatic field. When a conductor, such as a human finger, touches the surface of the first member 14 a capacitor is dynamically formed with the conductive tracks. An underlying controller printed on the second member 18 can then determine the location of the user's touch indirectly from the change in the capacitance as a result of the touch. This in turn can be used to control the underlying electronic components 30, 32, 34. The three dimensional grooves 26, 40, and the slider function provided by a user sliding their finger through the groove 26 of the first member 14, may be implemented by means of a piezoelectric or capacitive touch function.

In practice the capacitive touch effect may be enhanced if a ground plane is incorporated into the structure at the rear of the second member 18 (i.e. on the opposite side to the moulded layer 22).

In the case of capacitive touch embodiments there is no need for intimate contact between an electrode layer and the first member 14 in the same way as for a piezoelectric-based activation, because the change in capacitance as a result of touch is enough to indicate control.

Many other layers may be incorporated into the structure to provide touch-sensitive or other user-control functions of the control unit 10, including resistive layers, piezoelectric layers, electromagnetic layers, Quantum Tunneling Composite (QTC) layers, electric field (e-field) layers and RF layers.

FIG. 11 is an alternative embodiment of the control unit in which the need for the second member of the structure is avoided and the electronic components 30, 32, 34 and conductive prints or tracks 38 are formed on the reserve side of the first member 14 (i.e. the surface on the reverse of that with which the user interacts). In this case the control unit is built up by first applying the graphical features 24 to the rear surface of the first member 14 and then applying a hard coat 50 to the front surface of the first member 14 to provide the protective layer. The electronic components and conductive tracks 38 are then applied to the rear surface of the first member 14, and the assembly is placed into a mould. The injection moulded material (e.g. polycarbonate) is introduced into the mould to produce the injection moulded layer on the reverse side of the first member 14, encapsulating the electronic components 30, 32, 34 and conductive tracks 38. The control unit structure in FIG. 11 can also be formed using a single shot injection moulding method to form the layer 22, as for FIG. 10.

A further alternative embodiment of the control unit may comprise having both the first and second members 14, 18 provided with electronic components, identified as 30, together with the necessary conductive tracks 38. As mentioned previously the first member 14 may be provided with a protective coating 50, although this is not essential. This embodiment may be particularly useful for a control unit which is configured for gesture control, wherein the electronic components need to be located close to the A surface of the control unit but other electronic components may be located on the B surface of the control unit. For example, it may be that one surface of the control unit is not of sufficient area to accommodate all the necessary electronic components, or alternatively it may be beneficial to spread the distribution of the electronic components, for example to minimize local heat generation from the components, in use. The control unit may be provided with a connector which is configured to apply the required currents to the electronic components. It may be desirable to control the electronic components on each of the first and second members 14, 18 using a common connector, as opposed to individual connectors being used for each one.

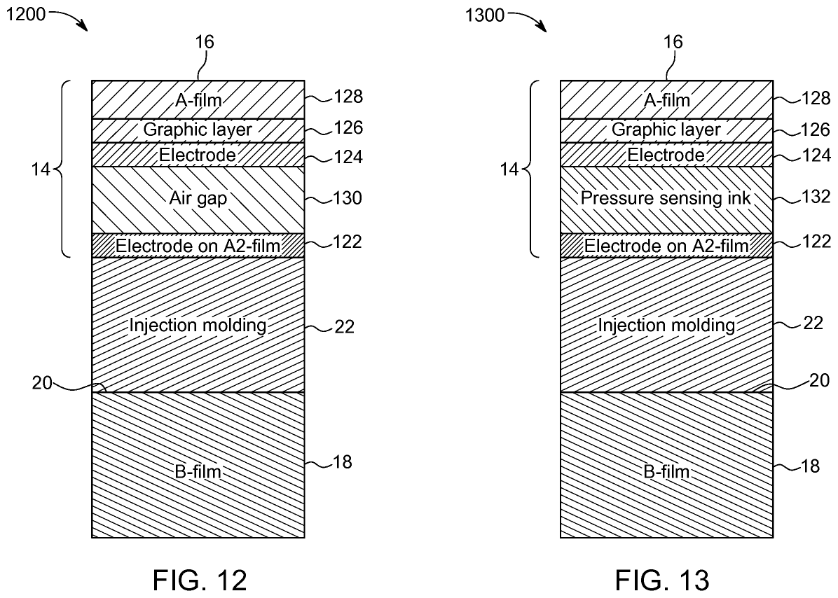

Referring now to FIGS. 12 and 13, there is shown schematic views of two possible configurations for implementation of the control apparatus. These implementations may be formed using a single shot injection moulding process in which the injection moulding material is introduced into the mould to form the intermediate layer 22 as per the control unit 10, as described previously.

FIG. 12 shows an implementation of a capacitive sensing element indicated generally by the reference numeral 1200 while FIG. 13 shows an implementation of a resistive sensing means indicated generally by the reference numeral 1300. The cross-sectional structures of both can be seen to be quite similar. The lowest layer of each structure corresponds to the second member 18 described previously. The second member is described in the figure using the term B-film, in that it is typically a film that provides the B surface. As previously described in relation to the B-surface of the second member 18, the B-film of FIGS. 12 and 13 may support one of more layers (not shown) of printed electronic circuitry and one or more active or passive electronic components (not shown).

Located above the B-film is the injection moulded layer 22, and above that is the first member 14. The first member 14 of the configurations shown in FIGS. 12 and 13 is formed from at least five distinct layers. Those layers comprise an A2-film layer 122 having a metal electrode layer (not shown) printed thereon. Above the A2-film layer 122 is a function layer, which will be described in more detail below. Above that is a further electrode layer 124, then a graphics layer 126 and finally an A-film 128 providing the A surface 16. The A-film 128 and the A2-film layer 122 are made from the same material. When a control apparatus using this configuration is being formed, the layers for the first member are built up as required either in the mould or prior to being placed in the mould. Then, during the injection moulding process, the heat causes the A-film 128 and the A2-film layer 122 to fuse together, thus forming the first member 14.

Referring now to FIG. 12, the function layer 130 is a layer that provides a capacitive sensing function. The capacitive function layer 130 may be an air gap layer, or may be a suitable dielectric layer. If an air gap is used, pillars (not shown) are formed between the electrode layers 122, 124 to space the layers apart and so form the air gap.

Referring now to FIG. 13, the function layer 132 is a layer that provides a resistive sensing function. The resistive function layer is printed using force resistive ink so as to provide a pressure sensing element.

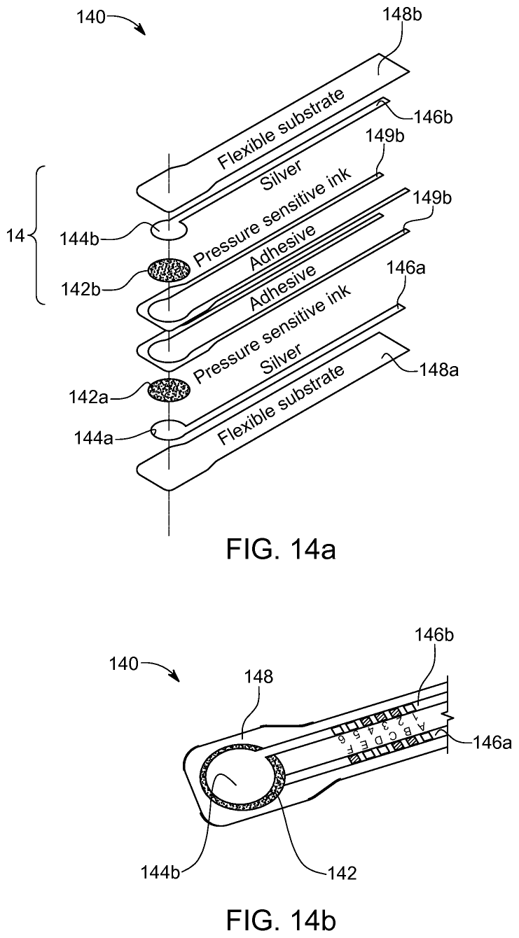

Referring to FIGS. 14(a) and (b), there is shown an exploded view of resistive pressure sensing means indicated generally by the reference numeral 140 suitable for use in embodiments of the control apparatus of the invention. The resistive pressure sensing means 140 is formed from a vertical “stack” 140 of layers of different materials and comprises two circular spots 142a, 142b of pressure sensitive ink, such as force resistive ink, located one above the other. When assembled the two spots 142a, 142b will be located together forming a single area of pressure sensing ink. Each spot 142a, 142b has a circular silver electrode 144a, 144b, located on the outer side of the spot in relation to the stack forming the resistive pressure sensing means 140. Each electrode 144a, 144b has an elongate track 146a, 146b extending therefrom. The tracks 146a, 146b from the two electrodes 144a, 144b are offset at their point of departure from the electrodes such that they do not overlie each other but are parallel to each other. The outer surfaces of the resistive pressure sensing means 140 are provided by a pair of flexible substrates 148a, 148b, corresponding to the A2-film 122 and A-film 128 of FIGS. 12 and 13 respectively. Two portions of adhesive 149a, 149b are provided to glue the two films 148a, 148b together without engaging with any of the spots 142a, 142b, electrodes 144a, 144b or tracks 146a, 146b. In production, the silver electrodes 144a, 144b and tracks 146a, 146b are printed onto their respective substrates 148a, 148b, and the pressure sensitive ink spots 142a, 142b are printed over the electrodes. In particular, the upper electrode 144b and track 146b and pressure sensitive ink are printed onto the reserve side of the A-film, forming the first member 14.

In an alternative embodiment (not shown), the pressure sensitive inks spots are very small, typically having a diameter around 1 mm and are in the form of a bubble or dimple. This embodiment uses the concept of pressure, P, being equal to the force, F, being divided by the area, P=F/A. Reducing the relevant area by using very a very small boss of pressure sensitive ink increases the pressure for the same force applied. In this way, the sensitivity requirement of the pressure sensitive ink is reduced. The area of pressure detection and applied pressure contribute to the determination of the dimensions of the ink spot. In an embodiment, the ink spot will be substantially hemispherical.

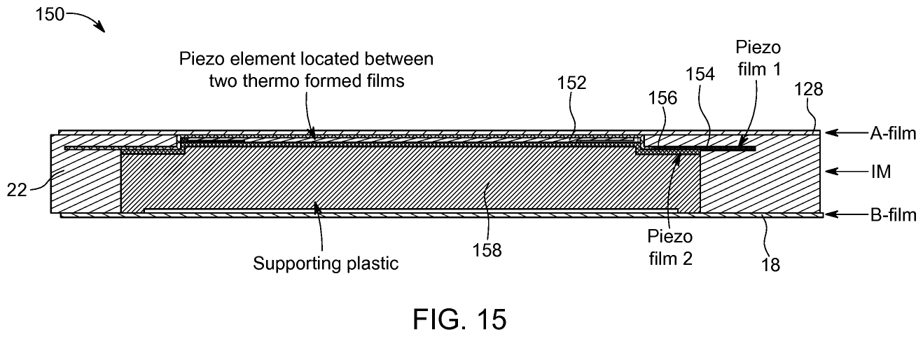

FIG. 15 is a cross section view of a piezoelectric pressure sensor indicated generally by the reference numeral 150 suitable for use as a pressure sensing means in an embodiment of the invention. FIG. 15 shows a piezoelectric sensor 150 implemented within the structure described in relation to FIGS. 8 to 14. The sensor 150 comprise a first member 14 separated from a second member 18 by an injection moulded layer 22. The sensor 150 further comprises, as function layers, a piezoelectric element 152 located between two thermoformed piezoelectric films 154, 156. The piezoelectric materials are supported just below the A-film 128 by some supporting film by a plastic support 158. The plastic support has a raised central portion with a lower step at each end. The second thermoformed piezoelectric film 156 sits directly on top of the plastic support, extending to the edges of the lower step thereof. The piezoelectric element 152 extends over the central portion, itself having a central portion in contact with the second thermoformed piezoelectric film 156 with flanges extending to the edge of the central portion of the plastic support. The first thermoformed piezoelectric film 154 lies over the top of the piezoelectric element 152, extending beyond the edges of the plastic support.

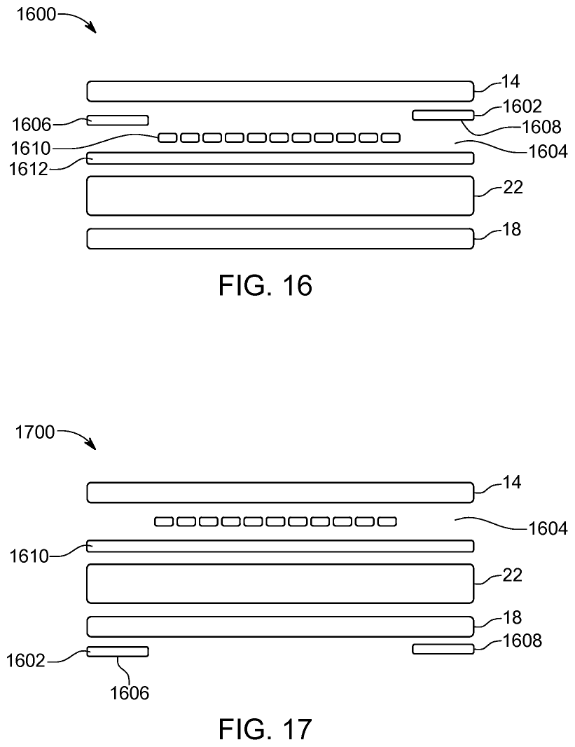

FIG. 16 is an exploded view of a cross-section schematic of an embodiment of a control apparatus according to the invention. The control apparatus, indicated generally by the reference numeral 1600, comprises a first member 14 including a substrate (not shown) supporting a number of other layers including a graphics layer (not shown), a protective layer (not shown), and an electrode layer (not shown) on the reserve side of the substrate. The control apparatus 1600 further comprises an injected moulded layer 22 and a second member 18, the second member 18 comprising a circuit carrying layer (not shown) and electronic components (not shown). The control apparatus 1600 further comprises a first sensing layer 1602 and a second sensing layer 1604. The first sensing layer implements a first pressure sensing means 1606 and a second pressure sensing means 1608. It will be apparent to the person skilled in the art that a number of suitable pressure sensors may be implemented as the first pressure sensing means and second pressure sensing means. The first pressure sensing means 1606 is located below one end of the first member 14 and the second pressure sensing means 1608 is located below the opposite end of the first member 14. The second sensing layer 1604 comprises a gesture sensing means 1610, in this case a row of capacitive sensing elements suitable for detecting a user's touch. Eleven capacitive elements are illustrated however it will be appreciated that a larger or smaller number of elements may be used. The capacitive sensing elements may take the form of simple printed metal plates wherein a user's finger acts as second conductor forming a capacitor with a plate when it is located above that plate. The metal plates may be printed on the A2 film 1612 located between the sensing layers and the injection moulded layer.

Referring now to FIG. 17, there is shown an exploded view of a cross-section schematic of a further embodiment of a control apparatus according to the invention, indicated generally by the reference numeral 1700. The control apparatus 1700 includes all of the components, structure and features of the control apparatus 1600 and therefore to avoid repetition only the additional components, structure and features are described. In this embodiment, the first sensing layer is located on the reserve side of the second member 18.

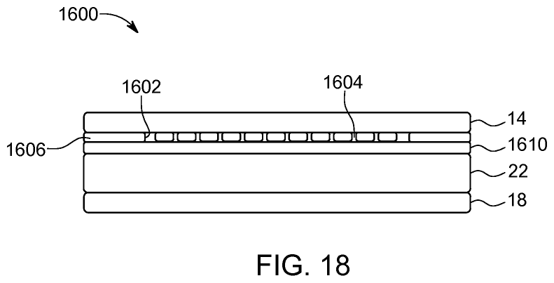

FIG. 18 is a cross-section schematic of the embodiment of the control apparatus 1600 shown in FIG. 16. This non-exploded view shows that when assembled the features implemented in the first sensing layer and those implemented in the second sensing layer slot in around each other such that may be considered a single layer.

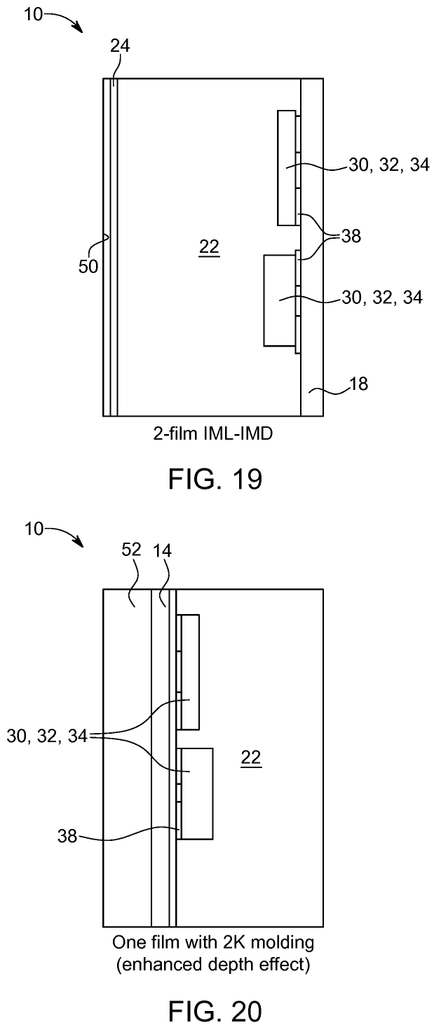

FIGS. 19 and 20 show alternative embodiments which may be formed using a twin shot (2K) injection moulding method. FIG. 19 is similar to the embodiment of FIG. 10 in that the electronic components 30, 32, 34 and the conductive prints 38 are mounted on the second member 18 and are spaced from the front surface of the control unit 10 by the moulded layer 22. However, the need for the first member is removed in this embodiment. Instead, the graphical features 24 are laid into a mould and the second member 18 is laid into a facing mould. A first shot of injection moulding material is then introduced into the gates 44 to fill the cavity between the moulds, and the material is cooled and set. Using a second mould the hard coat 50 is then formed at the front face of the structure using a second shot of injection moulded material (i.e. the hard coat is formed directly onto the moulded layer 22).

FIG. 20 is a further alternative embodiment in which a second shot of injection moulded material is used to produce enhanced depth effects at the front surface of the control unit 10. In this embodiment only one member 14 is required to support the electronic components 30, 32, 34 and conductive tracks 38. These components and tracks are applied immediately behind the graphical features 24 which are applied on the rear surface of the first member 14, as described for FIG. 5. A first shot of injection moulded material is then applied into a mould to encapsulate the rear surface of the first member 14, together with the electronic components 30, 32, 34 and the graphical features 24. A second shot of injection moulded material is then injected into a facing mould to encapsulate the front face of the first member 14, and to define a relatively thick and transparent front layer 52. The depth of the transparent layer 52 on the front of the structure can be used to provide enhanced depth effects for the graphical features 24 on the rear surface of the first member 14. For example, the transparent layer may be provided with various cut outs or holes of varying shapes and depths to provide different illumination effects from the LEDs 30, 32, 34.

In other embodiments (not shown) the hard protective coating 50 applied to the front surface of the first member 14 may take the form of a veneer, such as a wood effect veneer, which matches or complements the trim of the vehicle cabin in which the control unit 10 is intended to be used. In this way the control unit, comprising the control apparatus of the invention, readily lends itself to occupying a prominent location within the vehicle cabin, and as such can be accommodated within an arm rest, overhead panel or the dashboard, for example, due to its aesthetically attractive finish. For example, the veneer may take the form of any thin layer of suitable material, such as wood, carbon-fibre, polymer heat shrink plastic, metal, textile or leather.

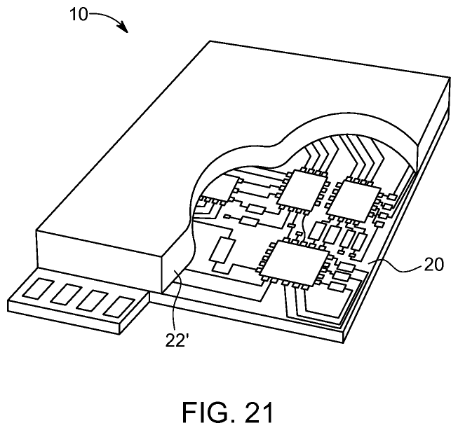

FIG. 21 shows a further alternative embodiment in which the encapsulation of the printed electronic components by the moulded layer 22′ is only partial across a surface of the structure. This may be useful, for example, if the accommodation space for the control unit is particularly limited, and the unit can be located partially within an already enclosed and safe environment without the need for extra encapsulation across the entire printed electronics layer.

Because of the high temperatures and pressures of the aforementioned injection moulding process, and despite the careful positioning of the gate(s) away from the most fragile and sensitive electronic components, some damage may occur to the conductive elements or tracks as the injected material is introduced through the gate(s) into the mould cavity. For this reason it may be beneficial to locate active electronic components in positions away from the gates 44, and passive electronic components closer to the gates 44, as the passive components are less likely to be susceptible to damage.

In addition, some electronic components require a higher current for performance (e.g. higher powered LEDs), so it is beneficial to allow for redundancy of these tracks to ensure that, even allowing for some breakage or damage during the injection moulding process, enough current can be delivered to the components through the remaining tracks which are not broken or damaged.

For the reasons described above the selection criterion for where particular components are located may be to locate active electronic components away from the gates, and passive components in closer proximity to the gates. Another criterion may be to consider whether a component is critical for the desired functioning of the control unit 10. If a component is considered critical to the operation of a control unit (for example, an LED light that provides illumination for a control unit for an indicator), then it is beneficial to locate the critical component away from the location of the gate so that the likelihood of damage to the conductive tracks supplying current to the LED, and/or damage to the LED itself, is minimised. It is also beneficial to locate the more fragile copper conductive tracks of the B-surface further away from the gates, whereas the silver conductive tracks may be more robust to the high pressure flows through the gates during injection moulding.

To counter any damage which may arise, it may be beneficial to provide an excess of conductive prints or tracks to provide some redundancy for the tracks in the event that such damage arises. In particular, redundant conductive tracks 38 may be provided in the regions local to the gate(s) 44, which are those regions most susceptible to damage as they experience the highest pressures.

Another problem which may arise is that the cooling and curing process which follows the high temperatures and pressures associated with the injection moulding process may lead to shrinkage and breakage of the tracks 38 due to the deformation of the underlying layer or substrate to which they are applied. Care therefore needs to be taken in selecting an appropriate ink viscosity for the conductive tracks 38 and the density of the track lines. The size and density of the tracks is dependent not only on the positioning relative to the gates, but also the electrical load requirements for the components to which the tracks connect.

As described further below, other methods of manufacturing the control apparatus of the invention may be employed to avoid the aforementioned problems altogether.

In order to provide additional protection for the more thermally sensitive electronic components it may be beneficial to incorporate a heat-sink arrangement into the control unit to transfer heat that builds up during the injection moulding process away from the sensitive components. The provision of a heat-sink arrangement also has benefits in operation of the control unit as it allows heat that is generated in use to be dissipated away from the areas of the control unit which may be damaged or caused to malfunction in the event of overheating.

A further alternative embodiment (not shown) makes use of a heat-sink feature which does not form a part of the final control unit 10 structure, but instead forms a part of the manufacturing tool used for the injection moulding process. This provides protection from heat for the electronic components during manufacture only.

In a still further embodiment (not shown) in which a heat sink arrangement is employed, a Peltier heat pump or a loop heat pipe may be used in combination with the thermally conductive element so as to provide a means of active control of heating or cooling of the encapsulated electronic circuit.

In other embodiments it is envisaged that the thermally conductive heat sink arrangement may be configured to conduct heat to the printed electronic circuit, for example, without limitation if there are other features of the control unit 10 require heat to be transferred away from them.

It will be appreciated from the foregoing description that the invention provides a robust, lightweight structure for the control unit 10 which lends itself to be located within a vehicle cabin where it is visible to the user due to the high-quality and versatile finish that can be achieved on the A-surface 16 with which the user interacts. One such embodiment is the over head control panel described previously and as shown in FIG. 2. Other applications for the control unit include an arm rest control panel for controlling the vehicle windows or door locks, a centre console control panel for controlling the vehicle's entertainment system, or as a lid of a glove compartment where a presentation surface can be presented to the user on the otherwise dead-surface of the glove compartment lid.

In another embodiment (not shown), the control unit 10 forms a part of a vehicle sun-visor. Typically, the sun-visor in a vehicle takes the form of a pull-down flap which obscures a region of the windscreen when in its pulled-down configuration so as to reduce glare for the user, but can be stowed in an upper substantially horizontal configuration, resting against the top of the windscreen frame, when not in use. Conventional sun visors are often provided with a vanity mirror and a light source which illuminates the area around the mirror and the user's face when the sun visor is pulled down. The light source is either operable by a switch on the sun visor or may light up automatically as the visor is pulled down. In the present invention the control unit 10 may be mounted on the sun visor so that the electronic components (whether mounted on the reverse of the A-surface or on a B-surface) are packaged conveniently within the sun visor unit to provide enhanced functionality for the lighting. By way of example, the level of lighting provided by the light source may be controlled in dependence on ambient lighting levels, or the timing of illumination from the light source may be controlled in dependence on other vehicle parameters or operating modes. The invention therefore enables an integrated light emitting system to be provided in the small confines of a vehicle sun visor to give improved lighting features.

In other embodiments of the invention when utilised in a vehicle, the control unit 10 may take the form of a display panel for presenting information to the user, rather than providing an interaction surface for the user. For example, the control unit may be configured to control a hidden-until-lit feature of the vehicle whereby illumination of the feature by a light source (e.g. LED) of the control panel highlights the feature to the user which is otherwise not visible.

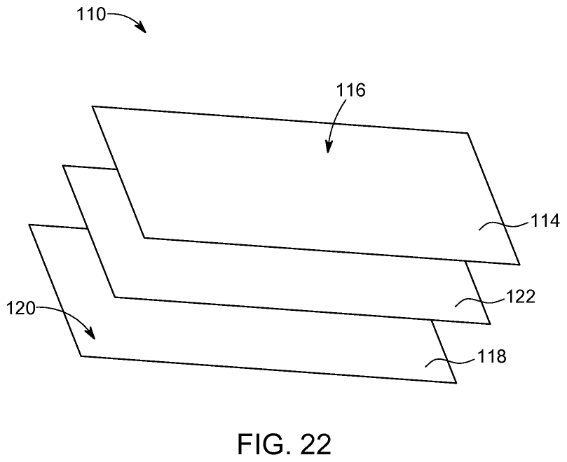

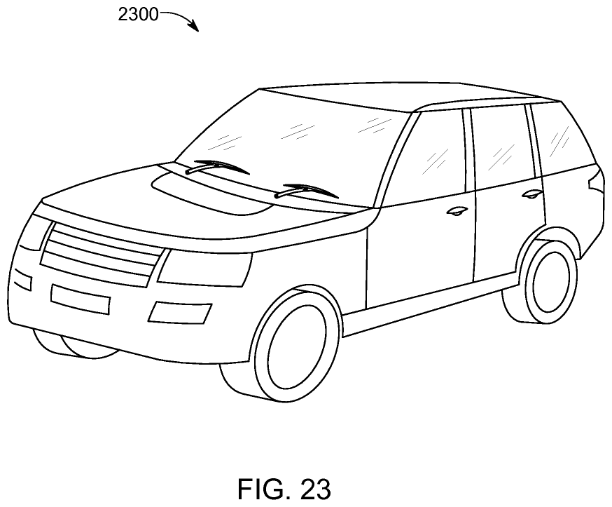

Certain of the previously described embodiments of the invention are formed using an injection moulding process to produce the intermediate layer and/or the encapsulation layer(s). In order to avoid the problems associated with the high temperatures and pressures of the injection moulding process, alternatively the control unit structure may be formed using a lamination process to replace the injection moulded layer with a laminate layer. FIG. 22 is a schematic diagram to show a control apparatus 110 of one embodiment of the invention when formed using laminate layers. As described previously, the first member 114 defines an A-surface 116 which carries graphical features as indicators to the user about how to control the unit. The second member 118 defines a B-surface 120 which carries the various electronic components and conductive tracks (not shown in FIG. 11). The third member 122, which is situated between the first and second members 114, 118, takes the form of a lamination layer such as a glue layer.

In order to assemble the control apparatus 110 using the lamination process the first member 114 is first pre-formed using a thermoforming process, as described previously, and is laid into a mould. The second member 118 is formed using a similar process, as described previously, and is laid into a facing mould. The glue layer 122 is then laid onto the first or second member. The glue layer is pre-warmed so that it is pliable, but is formed of a material that does not require excessive pre-warming to give the required pliability.

Once the glue layer 122 is laid onto the first or second members 114, 118 the mouldings are brought together to apply pressure to the parts, sandwiching the glue layer 122 between the first and second members 114, 118. Heat is then applied to the structure so that the glue moulds itself exactly to the shape of the first and second members 114, 118 and adheres the parts together. The presence of the glue on the second member 118 is beneficial in that it provides a protective layer for the electronic components and circuitry during the heating phase. Moreover, as the glue layer is heated its phase change from a more solid to liquid form takes energy away from the components and circuitry. Finally the assembled structure is cooled so that the glue ‘sets’ to fix the first and second members 114, 118 securely together in a rigid structure with the glue forming an intermediate layer 122 between them.

In another embodiment (not shown) in which a laminate glue layer is used to hold the members of the control apparatus together, the need for two base members 114, 118 may be removed if the graphical features are laid directly into a mould rather than applying them to a first member 114. The glue is then laid directly into the mould, on top of the graphical features, and is sandwiched together with the second member 118 to form a two-layer structure with the graphical features being embedded or imprinted on the surface of the glue layer.

In a still further embodiment (not shown) the control apparatus may comprise two or three layers formed from a lamination process so that the layer upon which the electronic components and conductive tracks are printed is a flexible sheet or layer, rather than taking a rigid pre-form.

One benefit of the glue lamination process is that the high temperatures and pressures required for the injection moulding process are avoided. In addition, there is no need to accommodate gates within either the first and/or second members 114, 118 as the glue is simply laid onto one of the layers in pliable form. The lamination process also enables the stacking of integrated circuit components onto the B-surface (or the reverse of the A-surface) which may not otherwise be achievable due to the high temperatures and pressures of the injection moulding process which would too readily deform the stacked circuitry. Suitable materials for the lamination process include resins, vinyls, and ethylene copolymer resins.

Other embodiments envisage a hybrid arrangement of a laminated control unit structure in one part of the vehicle which is integrated with a moulded control unit structure in a common assembly. For example the arm rest of the vehicle may include a moulded high gloss unit with a wood-effect veneer having the control functions of the A-surface, with the laminated unit being adjacent to it to provide the resting surface for the arm.

Referring now to FIG. 23, there is shown a perspective view of a vehicle 2300 comprising the control apparatus, control units or the component as described herein. The control apparatus (not shown) has particular application in a vehicle 2300, wherein the control apparatus is configured to allow the user to control the operation of a function of the vehicle, for example a function in the form of control of the lighting system, the heating system, the entertainment system, the seating system, the airbag system, the sun roof, or the window. Other embodiments envisage that the control apparatus may be used in a household appliance for user control thereof, and may be located within a control unit that forms a panel of a household appliance, such as electrical items in the form of washing machines, cookers or dishwashers and the like.

When used in a vehicle, the control apparatus provides the advantage that it is convenient to manufacture and in the final version provides a lightweight yet robust control apparatus that occupies little accommodation space within the vehicle. This is a particularly useful feature in modern day vehicles where vehicle functionality is high, and there is an ever increasing need for additional control functions. Furthermore, the printed electronic circuit is protected by the injection moulded layer which encapsulates the fragile and sensitive electronic components and circuitry.

It will be appreciated that embodiments of the present invention can be realised in the form of hardware, software or a combination of hardware and software. Any such software may be stored in the form of volatile or non-volatile storage such as, for example, a storage device like a ROM, whether erasable or rewritable or not, or in the form of memory such as, for example, RAM, memory chips, device or integrated circuits or on an optically or magnetically readable medium such as, for example, a CD, DVD, magnetic disk or magnetic tape. It will be appreciated that the storage devices and storage media are embodiments of machine-readable storage that are suitable for storing a program or programs that, when executed, implement embodiments of the present invention. Accordingly, embodiments provide a program comprising code for implementing a system or method as claimed in any preceding claim and a machine readable storage storing such a program. Still further, embodiments of the present invention may be conveyed electronically via any medium such as a communication signal carried over a wired or wireless connection and embodiments suitably encompass the same.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed. The claims should not be construed to cover merely the foregoing embodiments, but also any embodiments which fall within the scope of the claims.

1. A control apparatus for controlling operation of a component, the control apparatus comprising:
a user-interaction surface visible to a user of the apparatus; and
a first pressure sensor adjacent to a gesture sensor, the first pressure sensor being adapted to detect a first press input and the gesture sensor being adapted to detect a gesture input proximal to the control apparatus,
wherein the first pressure sensor and the gesture sensor are horizontally adjacent beneath the user-interaction surface, such that movement of a finger to provide the first press input and the gesture input are combinable to form a single command for controlling operation of the component.

2. A control apparatus as claimed in claim 1 formed from at least a first sensing layer implementing the first pressure sensor; a second sensing layer implementing the gesture sensor; a circuit-carrying layer, and an injection moulded layer.

3. A control apparatus as claimed in claim 1, wherein the gesture sensor is further adapted to detect the direction of the gesture input.

4. A control apparatus as claimed in claim 1, wherein the gesture sensor is further adapted to detect a swipe input.

5. A control apparatus as claimed in claim 1, further comprising a processor adapted to receive a signal from the gesture sensor based on the gesture input and a signal from the first pressure sensor based on the first press input; and further adapted to combine the signal from the gesture sensor and the signal from the first pressure sensor and output the command to the component based on the received signals.

6. A control apparatus as claimed in claim 5, wherein the processor comprises a timing module adapted to monitor the relative timing of the gesture input and the first press input, and the processor is adapted to output the command if the relative timing is within a certain limit.

7. A control apparatus as claimed in claim 1, wherein the first press input has a pressure above a first predetermined threshold.

8. A control apparatus as claimed in claim 1, adapted to generate a set of commands based on different inputs received.

9. A control apparatus as claimed in claim 1, wherein the gesture sensor is adapted to detect a gesture input in contact with the control apparatus.

10. A control apparatus as claimed in claim 1, wherein the gesture sensor is adapted to detect a gesture input in proximity to the control apparatus.

11. A control apparatus as claimed in claim 7, comprising a second pressure sensor separated from the first pressure sensor by the gesture sensor, wherein the command includes a second press input at the second pressure sensor.

12. A control apparatus as claimed in claim 11, wherein the second press input has a pressure above a second predetermined threshold.

13. A control apparatus as claimed in claim 12, wherein the first threshold input is equal to the second threshold input.

14. A control apparatus as claimed in claim 11, wherein the processor is adapted to receive a signal from the second pressure sensor in dependence on the second press input; and is adapted to output the command to the component based on the received signals.

15. A control apparatus as claimed in claim 11, wherein the timing module of the processor is adapted to monitor the relative timing of the gesture input, the first press input, and the second press input; and the processor is adapted to output the command if the relative timing are within a certain limit.

16. (canceled)

17. (canceled)

18. (canceled)

19. A control apparatus as claimed in claim 1, wherein the gesture sensor comprises a capacitive sensor that comprises a plurality of capacitive sensing elements that are arranged side by side, having increasing distance from the first pressure sensor.

20. (canceled)

21. (canceled)

22. A control apparatus as claimed in claim 1, wherein the gesture sensor comprises a resistive sensor that comprises force sensitive resistive ink.

23. (canceled)

24. A control apparatus as claimed in claim 1, wherein either or both the first pressure sensor and the second pressure sensor comprise one of a piezoelectric sensor, a resistive sensor, and a capacitive sensor.

25. (canceled)

26. (canceled)

27. (canceled)

28. (canceled)

29. A vehicle comprising the control apparatus of claim 1.

30. (canceled)

31. (canceled)

32. A method of controlling operation of a component, the method comprising:
receiving a first signal based on a first press input at a first pressure sensor that is arranged beneath a user-interaction surface visible to a user;
receiving a second signal based on a gesture input at a gesture sensor that is arranged beneath the user-interaction surface horizontally adjacent to the pressure sensor; and
outputting a command for the component if the signals indicate movement of a finger to provide a single command comprising a combination of inputs matching a predefined combination of inputs.

33. (canceled)
